(19) United States
(12) Patent Application Publication
(10) Pub. No.: US 2004/0246689 A1
(43) Pub. Date: Dec. 9, 2004

(54) Apparatus and method for mounting a surface mount component in an etched well in a printed circuit board

(76) Inventors: Ricardo E. Espinoza-Ibarra, Carmichael, CA (US); Sachin N. Chheda, Roseville, CA (US); Benjamin T. Percer, Roseville, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/452,222

(22) Filed: Jun. 3, 2003

(51) Int. Cl. H05K 7/06

(52) U.S. Cl. 361/761; 361/780

(57) ABSTRACT

A method and corresponding apparatus for mounting surface mount (SMT) components in a printed circuit board (PCB) add an aperture, i.e., an etched well, to the PCB to effectuate direct connection of high speed signals to the SMT components. The method eliminates the need of via and may be applied to any SMT components, such as inductors, resistors, capacitors, chips, and other components. In addition, since signal traces are shielded (not exposed to air), undesired side-effects, such as Electro-Magnetic Interference (EMI) and Cross Talk, and the like, may be reduced significantly. The method also ensures tighter signal impedance control and better propagation delay control. Additionally, faulty components may be replaced and/or repaired.

### TECHNICAL FIELD

The technical field relates to computer hardware design, and, in particular, to mounting surface mount (SMT) components in a printed circuit board.

### BACKGROUND

Currently, mounting surface mount (SMT) components in a printed circuit board (PCB) has many design shortfalls. FIG. 1 illustrates a prior art method of mounting SMT components 120 on a PCB 100. The PCB 100 is a board made up of different layers, including a component side layer 106 and a solder side layer 108. The different layers of the PCB 100 are used for different purposes, such as delivering power from one area of the PCB 100 to another, routing signal traces from one area of the PCB to another. A discreet SMT component 120 to be loaded onto the PCB 100 is generally attached to a PCB trace pad 140 before being mounted on the surface of the PCB 100.

High speed signals 110 typically travel on a signal layer 130 within a PCB 100. For accurate delivery of a high speed signal 110, impedance on the signal layer 130 needs to be controlled in such a fashion as not to degrade the quality of the signal 110. Generally, the PCB 100 has tighter control on the impedance of the inner layer of the PCB 100, such as the inner signal layer 130, than on the impedance of the outer layer of the PCB 100, such as the component side layer 106. Therefore, high speed signals 110 are typically delivered through one of the inner layers, such as the inner signal layer 130 shown in FIG. 1.

In circuit design, the high speed signal 110 may need to make connection with the SMT component 120. Since the SMT component 120 generally resides on the surface of the PCB 100, the signal trace needs to be routed from the surface of the PCB 100 onto the surface layer 135 in order to connect to the SMT component 120. In other words, the signal 110 needs to travel from a tightly impedance controlled layer to a more loosely impedance controlled layer, which is undesirable in circuit design. In addition, whenever the signal trace changes layers, a via 104 with metal surroundings needs to be added for signal conductance. The addition of via 104 introduces new inductance into the path of the signal 110, which is again undesirable.

Furthermore, routing the signal 110 onto the surface layer 135 will increase Electro-Magnetic Interference (EMI) radiation because the signal 110 is unshielded. In addition, there is higher susceptibility to “cross-talk” with other electromagnetic (EM) energy in the environment.

FIG. 2 illustrates another prior art design, i.e., using different types of photo-resist 250 and other materials, such as copper 210, to emulate having a SMT component 220 built into a PCB 200. High speed signals can continue on a single layer 230. However, the type of the component 220 is limited to either a resistor or inductor emulation with loose tolerances (>20%), which are not applicable for use in tightly controlled applications, such as advanced filtering and Digital Signal Processing (DSP), among others. In addition, since the component 220 is built into the PCB 200, replacing or repairing a later damaged component 220 may be practically impossible.

### SUMMARY

A method for mounting surface mount (SMT) components in a printed circuit board (PCB) includes determining a depth of a signal layer upon which a signal of interest travels in the PCB. The PCB includes a plurality of PCB layers. The method then creates an aperture for a component in each of the PCB layers from the component's side of the PCB to the signal layer and loads the component into the aperture at the signal layer in the PCB. The signal of interest connects with the component at the signal layer in the PCB.

The method eliminates the need of a via and may be applied to any SMT components, such as inductors, resistors, capacitors, chips, and other components. In addition, since signal traces are shielded, undesired side-effects, such as Electro-Magnetic Interference (EMI) and Cross Talk, and the like, may be reduced significantly. The method also ensures more precise signal impedance control and better propagation delay control. Additionally, faulty components may be replaced or repaired more conveniently than in the method depicted in FIG. 2.

An embodiment of the method for mounting SMT components in a PCB includes a signal layer upon which a signal of interest travels in the PCB. The PCB includes a plurality of PCB layers. An aperture is created to extend from the component's side of the PCB to the signal layer. A SMT component is loaded into the aperture at the signal layer in the PCB. The signal of interest connects with the SMT component at the signal layer in the PCB.

### DESCRIPTION OF THE DRAWINGS

The detailed description will refer to the following figures, in which like numerals refer to like elements, and wherein:

FIGS. 1 and 2 illustrate prior art methods of mounting surface mount (SMT) components;

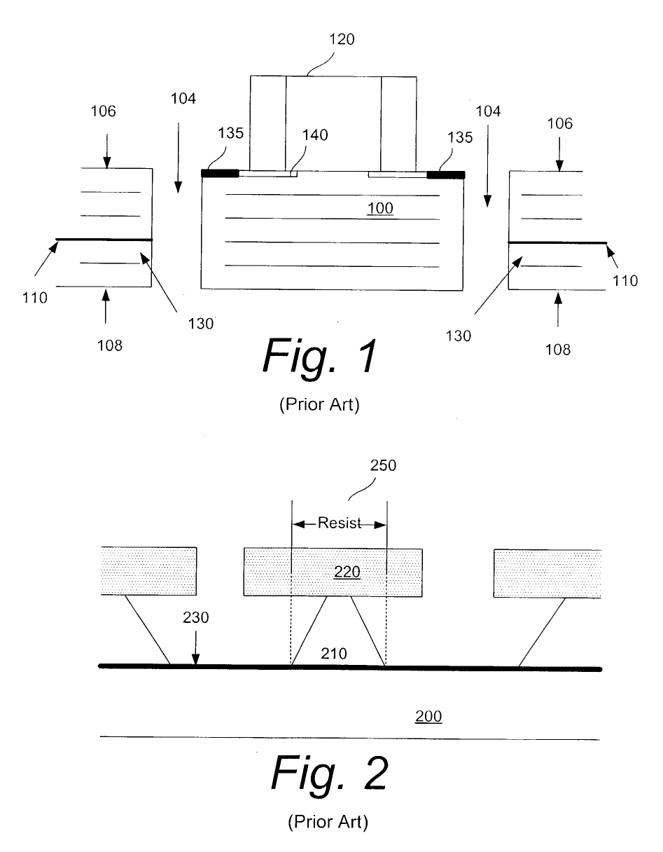

FIG. 3 illustrates an exemplary embodiment of a method for mounting SMT components in a printed circuit board (PCB);

FIG. 4 is a flow chart illustrating an exemplary method for mounting SMT components in a PCB; and

FIG. 5 illustrates exemplary hardware components of a computer that may be used in connection with the method for mounting SMT components in a PCB.

### DETAILED DESCRIPTION

A method and corresponding apparatus for mounting surface mount (SMT) components in a printed circuit board (PCB) create an aperture, i.e., an etched well, in the PCB to effectuate direct connection of high speed signals with the SMT components. The method eliminates the need of via and may be applied to any SMT components, such as inductors, resistors, capacitors, chips, and other components. In addition, since signal traces are shielded (not exposed to air), undesired side-effects, such as Electro-Magnetic Interference (EMI) and Cross Talk, and the like, may be reduced significantly. The method also ensures more precise signal impedance control and better propagation delay control. Additionally, faulty components may be replaced and/or repaired. Even though described in connection with high speed signals, the method and apparatus can be applied to other types of signals.

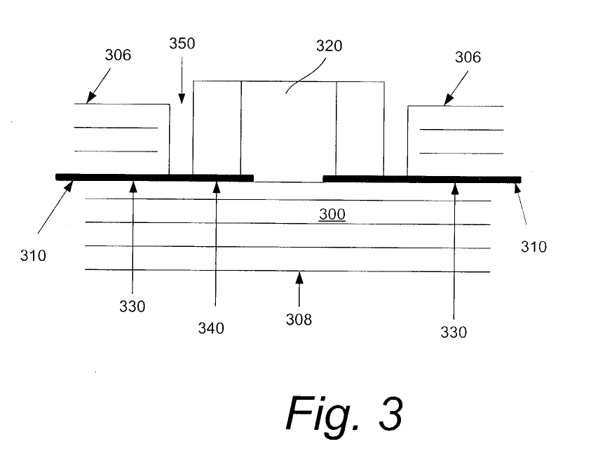

FIG. 3 illustrates an exemplary embodiment of a method for mounting SMT components 320 in a PCB 300. As noted above in the background section, the PCB 300 is a board made up of different PCB layers, including a component side layer 306 and a solder side layer 308. The different layers of the PCB 300 are used for different purposes, such as delivering power from one area of the PCB 300 to another, routing signal traces from one area of the PCB 300 to another, etc. Referring to FIG. 3, a high speed signal 310 typically travels on a signal layer 330. For accurate delivery of the high speed signal 310, impedance on the signal layer 330 needs to be more precisely controlled so as not to degrade the quality of the signal 310. As noted above, the PCB 300 typically has tighter control on the impedance of the inner layer of the PCB 300, such as the inner signal layer 330, than on the impedance of the outer layer of the PCB 300, such as the component side layer 306. Therefore, a high speed signal 310 preferably travels on one of the inner layers.

A SMT component 320 needs to make connection with a high speed signal 310 traveling on one of the inner layers of the PCB 300. With continued reference to FIG. 3, during a PCB fabrication process, a circuit designer first determines the depth of the signal layer 330 upon which the high speed signal of interest 310 travels. After the depth of the signal layer 330 is determined, the method may create a cavity, i.e., an aperture 350, in the PCB 300 in each of the PCB layers. The aperture 350 preferably extends from the component side layer 306 of the PCB to the signal layer 330, as shown in FIG. 3. The depth of the cavity for the placement of the SMT component 320 can be determined by the layer upon which the signal of interest 310 is routed and by the stack-up of the PCB 300.

During a printed circuit assembly (PCA) process, solder paste or other attach materials may be added to a PCB trace pad 340 (preferably loaded at the bottom of the aperture 350) for attaching the SMT component 320 to the PCB trace pad 340. Next, the SMT component 320 may be loaded into the aperture 350 at the signal layer 330.

Since the aperture 350 has a similar depth as the signal layer 330 and the PCB trace pad 340 is preferable loaded at the bottom of the aperture 350, the PCB trace pad 340 allows for direct connection of the high speed signal 310 to the SMT component 320. Because no extra discrepancies exists in the signal path, the high speed signal 310 does not need to travel on different PCB layers, leading to more efficient signal delivery, tighter signal impedance control, and better propagation delay control. In addition, since the high speed signal traces are routed along the inner layers of the PCB 300 and shielded, Electro-Magnetic Interference (EMI) may be reduced significantly. Further, when the SMT component 320 is damaged, the SMT component 320 can be replaced and/or repaired by ordinary SMT rework.

A keep-out area (not shown) may be added in the cavity, i.e., aperture 350, around the SMT component 320 at, for example, the signal layer 330. The keep-out area helps to prevent electronic shorts during the fabrication, manufacturing and testing process. This feature is well known in the art.

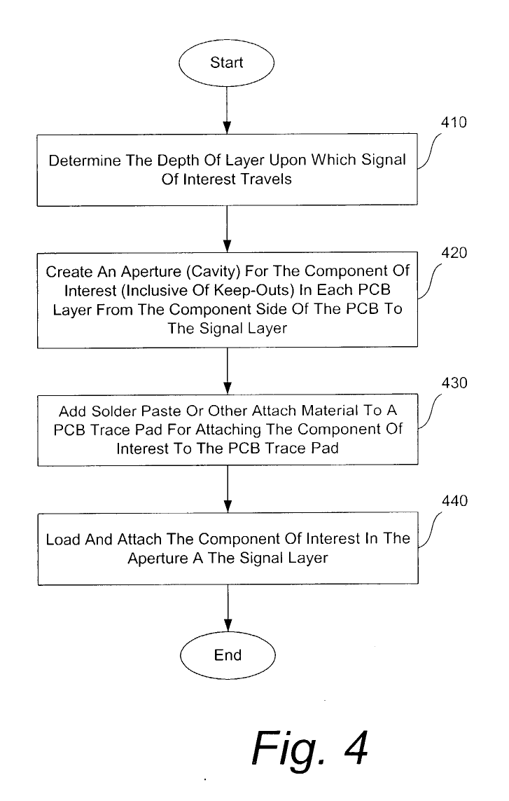

FIG. 4 is a flow chart illustrating an exemplary method for mounting SMT components 320 in a PCB 300. Before or during a PCB fabrication process, the method first determines a depth of a signal layer upon which a signal 310 of interest travels in the PCB 300 (step 410). The PCB 300 has a component side and includes a plurality of PCB layers. Then the method creates a cavity, i.e., aperture 350, for a SMT component 320 of interest (inclusive of the keep-out area) in each of the PCB layers. The aperture 350 preferably extends from the component side of the PCB 300 to the signal layer 330 (step 420). Next, during a PCA fabrication process, the method adds solder paste or other appropriate attach material to a PCB trace pad 340 for effectively attaching the SMT component 320 to the PCB trace pad 340 (step 430). Finally, the method loads and attaches the SMT component 320 into the aperture 350 at the signal layer 330 in the PCB 300 (step 440). The signal 310 of interest preferably connects with the SMT component 320 at the signal layer 330 in the PCB 300.

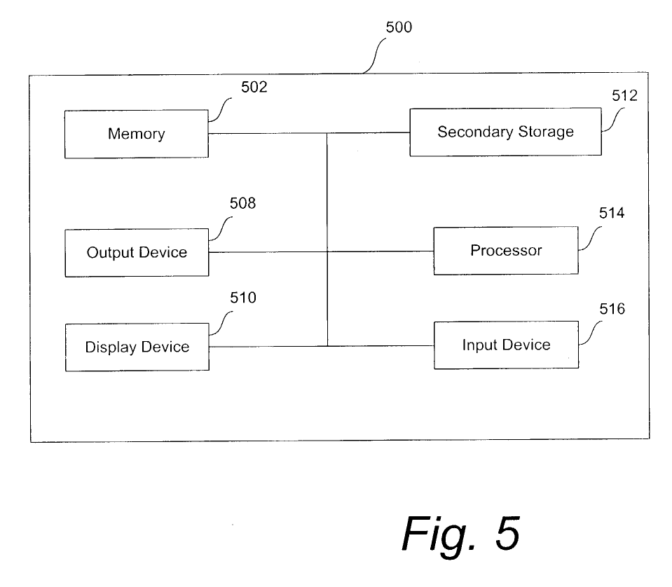

FIG. 5 illustrates exemplary hardware components of a computer 500 that may be used in connection with the method for mounting SMT components 320 in a PCB 300. The computer 500 typically includes a memory 502, a secondary storage device 512, a processor 514, an input device 516, a display device 510, and an output device 508.

The memory 502 may include random access memory (RAM) or similar types of memory. The secondary storage device 512 may include a hard disk drive, floppy disk drive, CD-ROM drive, or other types of non-volatile data storage, and may correspond with various databases or other resources. The processor 514 may execute information stored in the memory 502, the secondary storage 512, or received from the Internet or other network 518. The input device 516 may include any device for entering data into the computer 500, such as a keyboard, keypad, cursor-control device, touch-screen (possibly with a stylus), or microphone. The display device 510 may include any type of device for presenting visual image, such as, for example, a computer monitor, flat-screen display, or display panel. The output device 508 may include any type of device for presenting data in hard copy format, such as a printer, and other types of output devices including speakers or any device for providing data in audio form. The computer 500 can possibly include multiple input devices, output devices, and display devices.

Although the computer 500 is depicted with various components, one skilled in the art will appreciate that the computer 500 can contain additional or different components. In addition, although aspects of an implementation consistent with the method for mounting SMT components in a PCB are described as being stored in memory, one skilled in the art will appreciate that these aspects can also be stored on or read from other types of computer program products or computer-readable media, such as secondary storage devices, including hard disks, floppy disks, or CD-ROM; a carrier wave from the Internet or other network; or other forms of RAM or ROM. The computer-readable media may include instructions for controlling the computer 500 to perform a particular method.

While the method and apparatus for mounting SMT components in a PCB have been described in connection with an exemplary embodiment, those skilled in the art will understand that many modifications in light of these teachings are possible, and this application is intended to cover any variations thereof.

What is claimed is:

1. A method for mounting surface mount (SMT) components in a printed circuit board (PCB), comprising:
determining a depth of a signal layer upon which a signal of interest travels in the PCB, wherein the PCB includes a plurality of PCB layers;
creating an aperture for a component in each of the PCB layers from the component's side of the PCB to the signal layer; and
loading the component into the aperture at the signal layer in the PCB;
wherein the signal of interest connects with the component at the signal layer in the PCB.

2. The method of claim 1, further comprising adding attach material to a PCB trace pad for attaching the component to the PCB trace pad before the loading step.

3. The method of claim 1, further comprising adding a keep-out area in the aperture around the component to aid in a printed circuit assembly (PCA) manufacturing process.

4. The method of claim 1, wherein the determining and creating steps are accomplished during a PCB fabrication process.

5. The method of claim 1, wherein the determining step is accomplished before a PCB fabrication process.

6. The method of claim 1, wherein the loading step is accomplished during a printed circuit assembly (PCA) fabrication process.

7. The method of claim 1, wherein the signal of interest is a high speed signal traveling on an inner layer of the PCB.

8. The method of claim 1, further comprising replacing the component by removing the component from the aperture.

9. The method of claim 1, wherein the determining step includes determining the depth of the signal layer by the layer upon which the signal of interest is routed.

10. An apparatus for mounting surface mount (SMT) components in a printed circuit board (PCB), comprising:
a signal layer upon which a signal of interest travels in the PCB, wherein the PCB includes a plurality of PCB layers;
an aperture extending from the component's side of the PCB to the signal layer; and
a SMT component that is loaded into the aperture at the signal layer in the PCB, wherein the signal of interest connects with the SMT component at the signal layer in the PCB.

11. The apparatus of claim 10, further comprising a PCB trace pad for connecting the SMT component to the signal.

12. The apparatus of claim 10, further comprising a keep-out area in the aperture around the SMT component to aid in a printed circuit assembly (PCA) manufacturing process.

13. The apparatus of claim 10, wherein the depth of the aperture is determined during a PCB fabrication process.

14. The apparatus of claim 10, wherein the depth of the aperture is determined before a PCB fabrication process.

15. The apparatus of claim 10, wherein the SMT component is loaded during a printed circuit assembly (PCA) fabrication process into the aperture.

16. The apparatus of claim 10, wherein the signal of interest is a high speed signal traveling on an inner layer of the PCB.

17. The apparatus of claim 10, wherein the SMT component can be removed from the aperture for replacement.

18. A computer-readable medium comprising instructions for mounting surface mount (SMT) components in a printed circuit board (PCB), the instructions comprising:
determining a depth of a signal layer upon which a signal of interest travels in the PCB, wherein the PCB includes a plurality of PCB layers;
creating an aperture for a component in each of the PCB layers from the component's side of the PCB to the signal layer; and
loading the component into the aperture at the signal layer in the PCB;
wherein the signal of interest connects with the component at the signal layer in the PCB.
19. The computer-readable medium of claim 18, wherein the signal of interest is a high speed signal traveling on an inner layer of the PCB.
20. The computer-readable medium of claim 18, further comprising instructions for replacing the component by removing the component from the aperture.
